(19) United States
(12) Patent Application Publication
(10) Pub. No.: US 2025/0188612 A1
(43) Pub. Date: Jun. 12, 2025

(54) FILM DEPOSITION DEVICE

(71) Applicants: ACM RESEARCH (SHANGHAI), INC., Shanghai (CN); ACM Research Korea CO., LTD., Icheon-Si (KR); CleanChip Technologies Limited, Hong Kong (CN)

(72) Inventors: Hui Wang, Shanghai (CN); Shan Zhang, Shanghai (CN); Sulan Xie, Shanghai (CN); Hongcai Fei, Shanghai (CN); Tom Kim, Icheon-Si (KR); Jacob Lee, Icheon-Si (KR); William Baek, Icheon-Si (KR)

(73) Assignees: ACM RESEARCH (SHANGHAI), INC., Shanghai (CN); ACM Research Korea CO., LTD., Icheon-Si (KR); CleanChip Technologies Limited, Hong Kong (CN)

(21) Appl. No.: 18/847,165

(22) PCT Filed: Feb. 28, 2023
(86) PCT No.: PCT/CN2023/078594

§ 371 Date: Sep. 13, 2024

(30) Foreign Application Priority Data
Mar. 14, 2022 (CN) 202210247529.8

(51) Int. Cl. C23C 16/458; C23C 16/44; C23C 16/455; C23C 16/46; C23C 16/52

(52) U.S. Cl. CPC C23C 16/4584; C23C 16/4412; C23C 16/45508; C23C 16/4586; C23C 16/46; C23C 16/52

(57) ABSTRACT

Disclosed is a film deposition device, having a substrate supporting component and comprising: a central shaft and a supporting base set on the top of the central shaft; a rotary shaft and a supporting ring set on the top of the rotary shaft, wherein the supporting ring is arranged around the supporting base, and the supporting base and the supporting ring are used for supporting a central area and an peripheral area of a substrate respectively; a first actuator connected to the rotary shaft for driving the supporting ring to rotate; a second actuator for driving the supporting ring and the supporting base to move relatively in a vertical direction; and a buffer portion for performing buffering when the substrate comes into contact with the supporting ring. The buffer portion can generate a buffer force at the moment when the substrate comes into contact with the supporting ring, so as to absorb part of the impact force formed between the supporting ring and the substrate when the supporting ring comes into contact with the substrate, so that the problems of warping and fragmenting of the substrate caused by the impact force and the poor contact between the substrate and the supporting base are avoided, the contact between the substrate and the supporting ring is more stable and more reliable, and the substrate and the substrate supporting component are tightly attached when coming into contact with each other.

### BACKGROUND OF THE INVENTION

### Field of the Invention

The present invention generally relates to the technical field of semiconductor device fabrication, and more particularly to a film deposition device.

### The Related Art

In a semiconductor chip production process, a film deposition device is used to deposit various dielectric layers, metal layers, and the like on a substrate surface. The film deposition device is equipped with a substrate supporting component, which usually has a supporting base and a supporting ring arranged around the supporting base. The supporting base is used to support and heat the substrate, and the supporting ring is used to hold up the substrate.

In the process of moving the supporting ring relative to the supporting base to support or lift the substrate, at the moment when the supporting ring comes into contact with the substrate, a certain impact force will be generated between the supporting ring and the substrate. This will cause the substrate to warp or fragment, on the other hand, it will cause poor contact between the substrate and the supporting base, resulting in unstable support of the substrate.

During the film deposition process, the peripheral area of the substrate is in contact with the supporting ring, and the central area of the substrate is in contact with the supporting base. The supporting base can heat the substrate. However, the supporting ring does not have a heating function, so the peripheral area of the substrate cannot absorb heat directly from the supporting base under vacuum conditions. This causes the peripheral area of the substrate to be cooler than the central area of the substrate.

In addition, the substrate is often warped, which affects the reliability of the contact between the substrate and the substrate supporting component. There may be a gap between the substrate and the substrate supporting component, allowing the reactive gas to enter the backside of the substrate along the gap and forming an undesired film deposition on the backside of the substrate, thereby causing particle contamination of the substrate.

All the above factors will have adverse effects on the film properties on the substrate surface, such as deterioration of the uniformity and density of the film. Therefore, it is necessary to design a film deposition device to deposit a film with good film properties on the substrate surface to improve product yield.

### SUMMARY

In view of the above shortcomings of the prior art, the present invention provides a film deposition device to solve the problem of unsatisfactory properties of films deposited on the substrate surface, so as to improve product yield.

In order to achieve the above objects and other related objects, the present invention provides a film deposition device having a substrate supporting component, which comprises:
a supporting base and a central shaft, with the supporting base being fixed on the top of the central shaft for supporting the central area of the substrate;
a supporting ring and a rotary shaft, with the supporting ring being fixed on the top of the rotary shaft and arranged around the supporting base for supporting the peripheral area of the substrate;
a first actuator, connected to the rotary shaft and used to drive the supporting ring to rotate;
a second actuator, used to drive the supporting ring and the supporting base to move relative to each other in a vertical direction;
a buffer portion, for buffering when the substrate contacts the supporting ring.

Wherein, the buffer portion can generate a buffering force at the instant of contact between the substrate and the supporting ring to absorb part of impact force formed between the supporting ring and the substrate when the two are in contact. It prevents the substrate from warping, fragmenting, and poor contact with the supporting base due to the impact force. This makes the contact between the substrate and the substrate supporting component, especially the supporting ring, more stable and reliable, and achieves a close fit between the substrate and the substrate supporting component when in contact.

As an optional embodiment of the present invention, the buffer portion is set on the rotary shaft.

As an optional embodiment of the present invention, the substrate supporting component further comprises:
a pressure sensor, used to detect an actual contact pressure between the substrate and the supporting ring;
a controller, used to control the relative movement distance of the supporting ring and the supporting base according to the actual contact pressure detected by the pressure sensor, so that the actual contact pressure between the substrate and the supporting ring is within a set contact pressure threshold.

As an optional embodiment of the present invention, the pressure sensor is set below the rotary shaft.

The contact pressure between the substrate and the supporting ring can be accurately controlled by setting the pressure sensor, which can further ensure that the substrate is in close contact with the supporting ring and the supporting base. It is conducive to narrowing the gap between the substrate and the substrate supporting component, so as to avoid that the reactive gas enters the backside of the substrate along the gap during the film deposition process, forming an undesired backside deposition and adversely affecting the film deposition process.

As an optional embodiment of the present invention, the second actuator is connected to the rotary shaft and drives the supporting ring to move in the vertical direction relative to the supporting base through the rotary shaft.

As an optional embodiment of the present invention, the second actuator is connected to the central shaft and drives the supporting base to move in the vertical direction relative to the supporting ring through the central shaft.

As an optional embodiment of the present invention, the substrate supporting component further comprises:
a first heater, used to heat the supporting base;
a first temperature sensor, used to detect the temperature of the supporting base.

As an optional embodiment of the present invention, the substrate supporting component further comprises:
a second heater, used to heat the supporting ring;
a second temperature sensor, used to detect the temperature of the supporting ring.

As an optional embodiment of the present invention, the first heater and the second heater are independently controlled.

By arranging an independently controllable first heater and second heater in the supporting base and the supporting ring, independent temperature control of the central area and peripheral area of the substrate is achieved, and the temperature gradient of the central area and peripheral area of the substrate is eliminated. At the same time, since the supporting ring is supported by the rotary shaft with the buffer portion, the substrate and the substrate supporting component, especially the peripheral area of the substrate and the supporting ring, can be effectively contacted, thereby improving the heat transfer efficiency of the second heater to the substrate through the supporting ring. All of the above are beneficial to improve the uniformity of the temperature of the substrate, thus improving the uniformity of the film on the substrate surface.

As an optional embodiment of the present invention, the first heater is integrated with the supporting base, and the second heater is integrated with the supporting ring.

In specifically, the first heater and the supporting base can be integrated together by the way of embedded design or assembled design. For example, the first heater may be embedded inside the supporting base, or the first heater can be assembled under the supporting base through fasteners. Similarly, the second heater and the supporting ring can be integrated together by the way of embedded design or assembled design.

As an optional embodiment of the present invention, the outer circumferential surface of the supporting base is provided with several uniformly distributed first exhausts, and the several first exhausts are connected to a first gas path for supplying gas to the gap between the supporting base and the supporting ring.

The supply of gas to the gap between the supporting base and the supporting ring through the first exhausts will form a positive pressure seal on the backside of the substrate, and on the other hand, the gas will partially overflow from the gap between the substrate and the supporting ring, forming an air curtain at the outer edge of the substrate. These will prevent the reactive gas in the treatment chamber from escaping to the backside of the substrate, forming unnecessary backside deposition and thereby affecting the product yield.

As an optional embodiment of the present invention, the first gas path comprises:
a first gas source, used to provide gas;
a first main gas path, set in the central shaft;
multiple branch gas paths, radially distributed inside the supporting base;
a first buffer chamber, being set inside the supporting base and being an annular chamber coaxial with the supporting base;
wherein, the first main gas path is connected to the first gas source and multiple branch gas paths, and the first buffer chamber is connected to multiple branch gas paths and several first exhausts.

The first buffer chamber can buffer the gas pressure supplied by the first gas source, so that the gas discharge pressure of each first exhaust is the same. The gas discharged from the several first exhausts can form a gas curtain with the same air pressure in the entire circumferential direction of the substrate, so as to realize an effective interception effect on the reactive gases.

As an optional embodiment of the present invention, the inner circumferential surface of the supporting ring is provided with several uniformly distributed second exhausts, and the several second exhausts are connected to a second gas path for supplying gas to the gap between the supporting base and the supporting ring.

The supply of gas to the gap between the supporting base and the supporting ring through the second exhausts will form a positive pressure seal on the backside of the substrate, and on the other hand, the gas will partially overflow from the gap between the substrate and the supporting ring, forming an air curtain at the outer edge of the substrate. These will prevent the reactive gas in the treatment chamber from escaping to the backside of the substrate, forming unnecessary backside deposition and thereby affecting the product yield.

As an optional embodiment of the present invention, the second gas path comprises:
a second gas source, used to provide gas;
a second main gas path, set in the rotary shaft;
a second buffer chamber, being set inside the supporting ring and being an annular chamber coaxial with the supporting ring;
wherein, the second main gas path is connected to the second gas source and the second buffer chamber, and the second buffer chamber is connected to several second exhausts.

The second buffer chamber can buffer the gas pressure supplied by the second gas source, so that the gas discharge pressure of each second exhaust is the same. The gas discharged from the several second exhausts can form a gas curtain with the same air pressure in the entire circumferential direction of the substrate, so as to realize an effective interception effect on the reactive gases.

As an optional embodiment of the present invention, the supporting base is an electrostatic chuck, and the same electrode is provided in the supporting ring as in the supporting base for electrostatic adsorbing the peripheral area of the substrate.

By arranging electrodes in the supporting ring to electrostatically adsorb the peripheral edge of the substrate, the warping problem of the substrate can be improved, so that the peripheral area of the substrate is effectively in contact with the supporting ring and the gap between the substrate and the substrate supporting component is eliminated. On the one hand, it reduces the reactive gas from escaping into the backside of the substrate, and on the other hand, it can improve the thermal conductivity efficiency, and thus improve the yield of film deposition.

As an optional embodiment of the present invention, further comprising:
a treatment chamber, in which the substrate supporting component is located to support the substrate to be processed, wherein the rotary shaft and the central shaft of the substrate supporting component are sealed with the treatment chamber through magnetic fluid;
a gas distributor, located at the top of the treatment chamber and used to supply reactive gas into the treatment chamber to form a film on the surface of the substrate.

### BRIEF DESCRIPTION OF THE DRAWINGS

FIG. 1 is a sectional drawing of a film deposition device provided in embodiment 1 of the invention, wherein the substrate is supported by a supporting base.

FIG. 2 is another sectional drawing of the film deposition device provided in embodiment 1 of the invention, wherein the substrate is supported by a supporting ring and a supporting base.

FIG. 3 is another sectional drawing of the film deposition device provided by embodiment 1 of the invention, which shows a first gas path provided in the central shaft.

FIG. 4 is a sectional drawing of the supporting base provided by embodiment 1 of the invention, which shows the first gas path provided in the supporting base.

FIG. 5 is a sectional drawing along the A-A direction of FIG. 4.

FIG. 6 is a side view of the supporting base provided by embodiment 1 of the invention.

FIG. 7 is a sectional drawing of the film deposition device provided by embodiment 2 of the invention, which shows a second gas path provided in the rotary shaft and the supporting ring.

FIG. 8 is a sectional drawing of the supporting ring provided by embodiment 2 of the invention, which shows the second gas path provided in the supporting ring.

FIG. 9 is a sectional drawing along the B-B direction of FIG. 8.

### DETAILED DESCRIPTION OF EMBODIMENTS

The following illustrates the embodiment of the invention by means of particular specific examples, and other advantages and effects of the invention can be readily understood by those skilled in the art from the contents disclosed in this specification. The invention may also be implemented or applied in various other specific embodiments, and various details in this specification may be modified or changed based on different views and applications without departing from the spirit of the invention.

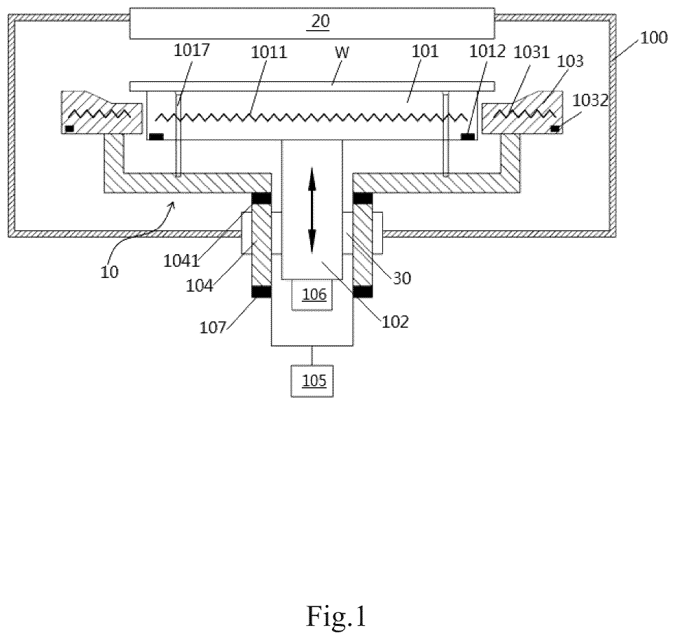

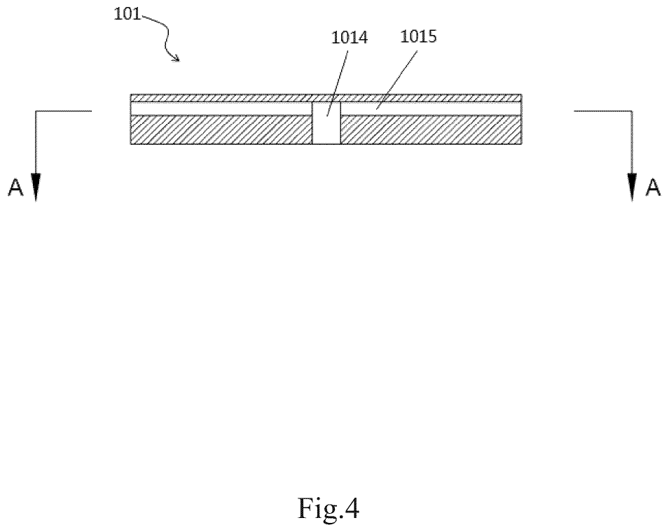

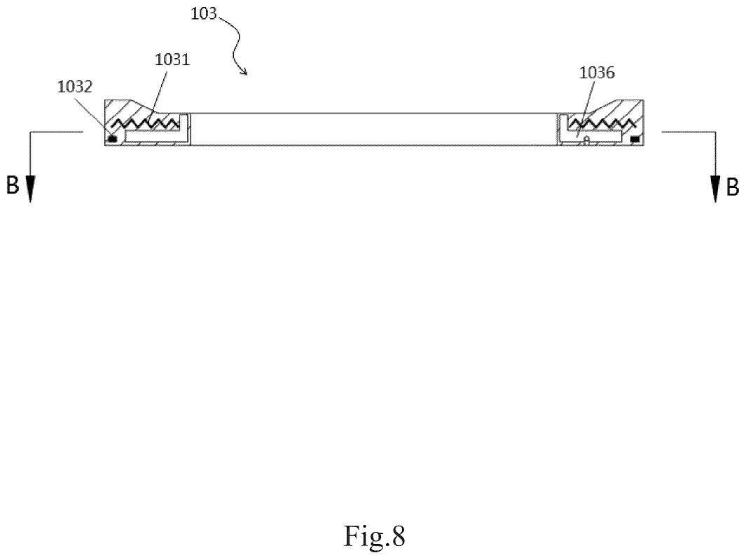

Referring to FIGS. 1 to 9, it should be noted that the diagrams provided by this embodiment only schematically illustrate the basic concept of the invention. Although only components related to the invention are shown in the diagrams rather than being drawn according to the number, shape, and size of components in actual implementation, the shape, quantity, and proportion of each component can be changed arbitrarily during actual implementation, and the layout of the components may be more complex.

### Embodiment 1

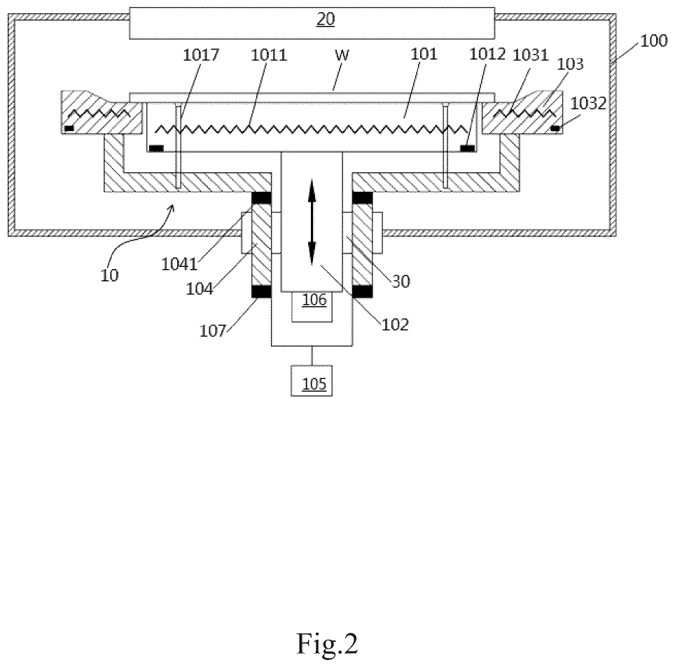

Referring to FIGS. 1 to 6, this embodiment provides a film deposition device. As shown in FIGS. 1 and 2, the film deposition device includes a treatment chamber 100, a substrate supporting component 10 and a gas distributor 20. The substrate supporting component 10, located in the treatment chamber 100, is used to support the substrate W to be processed. The gas distributor 20, located on the top of the treatment chamber 100, is used to supply reactive gas into the treatment chamber 100 to form a film on the substrate W surface.

The substrate supporting component 10 has a supporting base 101 and a supporting ring 103. Referring to FIGS. 1 and 2, the supporting base 101 is fixed on the top of the central shaft 102 for supporting the central area of the substrate W. The supporting ring 103 is fixed on the top of the rotary shaft 104 and is arranged around the supporting base 101 for supporting the peripheral area of the substrate W. In this embodiment, the rotary shaft 104 is a hollow shaft arranged coaxially with the central shaft 102 and is sleeved on the outside of the central shaft 102. The rotary shaft 104 and the central shaft 102 form a seal with the treatment chamber 100 through the magnetic fluid 30 to prevent external particles and other contaminants from entering the treatment chamber 100 and adversely affecting the film deposition process. In one embodiment, the supporting base 101 can be an electrostatic chuck. The central area of the substrate W is stably held on the supporting base 101 by the suction force of the electrostatic chuck. At the same time, in order to suppress warping in the peripheral area of the substrate W and improve its flatness when supported jointly by the supporting base 101 and the supporting ring 103, additional electrodes identical to those within the supporting base 101 can be added inside the supporting ring 103 to electrostatically adsorb the peripheral area of substrate W, ensuring effective contact between the peripheral area of the substrate W and the supporting ring 103.

The substrate supporting component 10 also has a first actuator 105 and a second actuator 106. The first actuator 105, connected to the rotary shaft 104, is used to drive the supporting ring 103 to rotate. The second actuator 106 is used to drive the supporting base 101 and the supporting ring 103 to move relative to each other in the vertical direction. In one embodiment, the second actuator 106 can be connected to the rotary shaft 104. The second actuator 106 drives the supporting ring 103 to rise and fall through the rotary shaft 104, so that the supporting ring 103 moves in the vertical direction relative to the supporting base 101. In another embodiment, the second actuator 106 can be connected to the central shaft 102. The second actuator 106 drives the supporting base 101 to rise and fall through the central shaft 102, so that the supporting base 101 moves in the vertical direction relative to the supporting ring 103.

The substrate supporting component 10 also includes a buffer portion 1041 for buffering when the substrate W contacts the supporting ring 103. In one embodiment, the buffer portion 1041 is located on the rotary shaft 104. The buffer portion 1041 has a certain elasticity and can play a buffering role when the substrate W contacts the supporting ring 103, ensuring smooth contact between the substrate W and the supporting ring 103. Preferably, the buffer portion 1041 can be disposed along the vertical direction. For example, the buffer portion 1041 is set coaxially with the rotary shaft 104. In one embodiment, the buffer portion 1041 is disposed between the rotary shaft 104 and the supporting ring 103; that is, the buffer portion 1041 is located on the top of the rotary shaft 104. In another embodiment, the buffer portion 1041 is located at the bottom of the rotary shaft 104. In other embodiments, the buffer portion 1041 can also be located in the middle of the rotary shaft 104. In addition, the buffer portion 1041 may also be located at the bottom of the supporting ring 103.

In normal operation, the relative displacement between the supporting base 101 and the supporting ring 103 can be determined by a displacement sensor. In this embodiment, in order to improve the reliability of the contact between the substrate W and the supporting ring 103, referring to FIGS. 1 and 2, the substrate supporting component 10 is further configured with a controller (not shown) and a pressure sensor 107. The pressure sensor 107 is used to detect the actual contact pressure between the substrate W and the supporting ring 103. The controller controls the second actuator 106 to control the relative movement distance between the supporting base 101 and the supporting ring 103 based on the actual contact pressure detected by the pressure sensor 107. So that the actual contact pressure between the substrate W and the supporting ring 103 is within the set contact pressure threshold. By controlling the relative displacement between the supporting base 101 and the supporting ring 103 in the force feedback mode, the contact pressure between the substrate W and the supporting ring 103 can be accurately controlled, which can further ensure that the substrate W is in close contact with the supporting base 101 and the supporting ring 103. It is conducive to narrowing the gap between the substrate W and the substrate supporting component 10, thereby preventing the reactive gas from entering the backside of the substrate W along the gap during the film deposition process, which would lead to undesirable back deposition and adversely affect the film deposition process. In one embodiment, the pressure sensor 107 is disposed below the rotary shaft 104 and outside the treatment chamber 100 to indirectly measure the contact pressure between the substrate W and the supporting ring 103. This can prevent the pressure sensor 107 from being in a high temperature environment, which helps reduce costs and extend the service life of the pressure sensor 107.

Referring to FIGS. 1 and 2, the substrate supporting component 10 also includes a first heater 1011 and a first temperature sensor 1012. The first heater 1011 is used to heat the supporting base 101 and heat the central area of the substrate W through the supporting base 101. The first temperature sensor 1012 is used to detect the temperature of the supporting base 101. Since the peripheral area of the substrate W cannot directly absorb heat from the radiating heated supporting base 101, in order to improve the heating uniformity of the peripheral area and central area of the substrate W, the substrate supporting component 10 can also be provided with a second heater 1031 and a second temperature sensor 1032. The second heater 1031 is used to heat the supporting ring 103 and heat the peripheral area of the substrate W through the supporting ring 103. The second temperature sensor 1032 is used to detect the temperature of the supporting ring 103. In this embodiment, the first heater 1011 and the second heater 1031 are independently controlled to achieve independent temperature control of the central area and peripheral area of the substrate W, thereby eliminating the temperature gradient in the central area and peripheral area of the substrate W. At the same time, due to the supporting ring 103 is supported by the rotary shaft 104 with the buffer portion 1041, which enables the substrate W to effectively contact the substrate supporting component 10, especially the peripheral area of the substrate and the supporting ring 103, thereby improving the heat transfer efficiency of the second heater 1031 to the substrate through the supporting ring 103. These are beneficial to improving the uniformity of substrate temperature, thereby obtaining better film uniformity.

In one embodiment, the first heater 1011 is integrated with the supporting base 101, and the second heater 1031 is integrated with the supporting ring 103. Specifically, the first heater 1011 and the supporting base 101 can be integrated together by the way of embedded design or assembled design. For example, the first heater 1011 may be embedded inside the supporting base 101, or the first heater 1011 can be assembled under the supporting base 101 through fasteners. Similarly, the second heater 1031 and the supporting ring can be integrated together by the way of embedded design or assembled design.

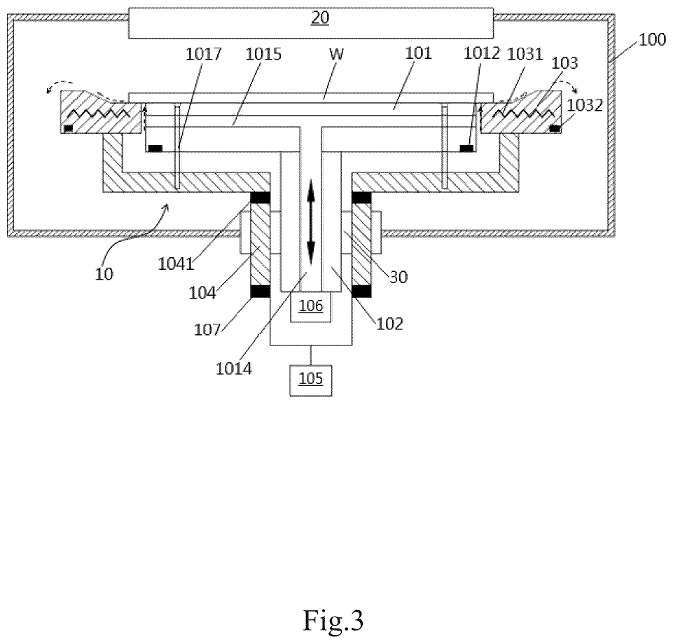

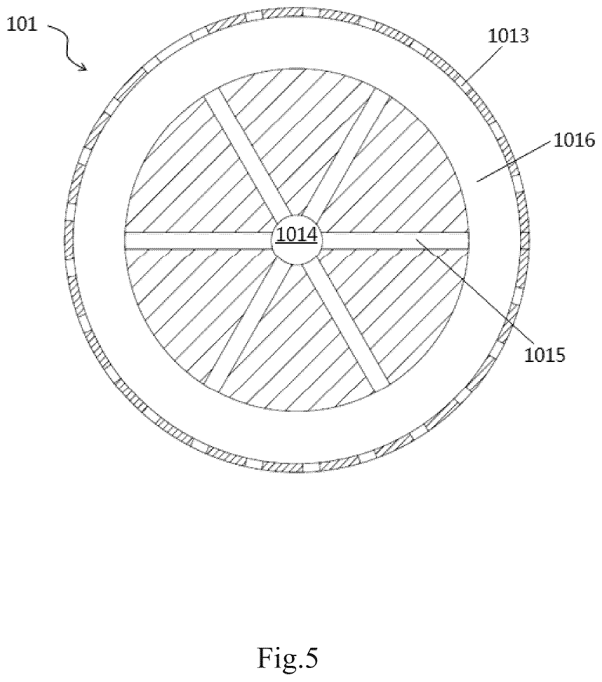

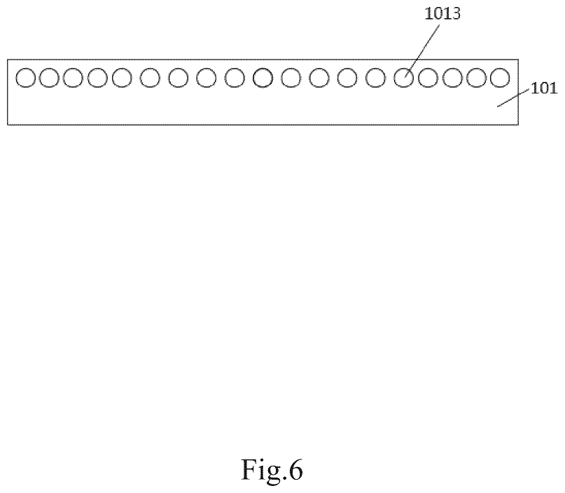

Referring to FIGS. 3 to 6, the substrate supporting component 10 further includes several first exhausts 1013. Referring to FIGS. 5 and 6, several first exhausts 1013 are evenly distributed on the outer circumferential surface of the supporting base 101 to supply gas, such as N₂, to the gap between the supporting base 101 and the supporting ring 103. On the one hand, the gas supplied to the gap through the several first exhausts 1013 will form a positive pressure seal on the backside of the substrate W, and on the other hand, the gas will partially overflow from the gap between the substrate W and the supporting ring 103, forming a gas curtain at the outer edge of the substrate W. These will prevent the reactive gases in the treatment chamber 100 from escaping to the backside of the substrate W, forming unnecessary backside deposition and thereby affecting the product yield.

The substrate supporting component 10 further includes a first gas path for supplying gas to several first exhausts 1013. Referring to FIGS. 3 to 6, the first gas path includes a first gas source (not shown), a first main gas path 1014, multiple branch gas paths 1015 and a first buffer chamber 1016 that are connected in sequence. The first gas source is used to provide gas. The first main gas path 1014 is set in the central shaft 102. The multiple branch gas paths 1015 are radially distributed inside the supporting base 101. The first buffer chamber 1016, located inside the supporting base 101, is an annular chamber coaxial with the supporting base 101. Wherein, the first main gas path 1014 connects the first gas source and the multiple branch gas paths 1015, and the first buffer chamber 1016 connects the multiple branch gas paths 1015 and several first exhausts 1013. The film deposition device generally performs the film deposition process under vacuum conditions. Accordingly, the treatment chamber 100 is provided with a vacuum exhaust, which is usually located at the bottom of the treatment chamber 100. Evacuating from the bottom of the treatment chamber 100 will facilitate the diffusion of gases discharged from several first exhausts 1013 towards the periphery of the substrate supporting component 10, forming the airflow indicated by the dashed arrows in FIG. 3.

The first buffer chamber 1016 can buffer the gas pressure supplied by the first gas source, so that the gas discharge pressure of each first exhaust 1013 is the same. The gases discharged from the several first exhausts 1013 can form a gas curtain with the same gas pressure in the entire circumferential direction of the substrate W, so as to realize an effective interception effect on the reactive gases.

The interior of supporting base 101 is usually equipped with a lifting pin 1017, which is used to assist in the transfer of the substrate W. The following will briefly introduce the actions of each component of the substrate supporting component 10 in conjunction with different process stages.

### Incoming Stage of Substrate W

The substrate W is delivered by the robotic arm into the treatment chamber 100 and placed on the lifting pin 1017. At this time, the lifting pin 1017 rises above the surface of the supporting base 101, and the supporting base 101 and the supporting ring 103 are located below the substrate W. After that, the robotic arm exits the treatment chamber 100, and the lifting pin 1017 drops below the surface of the supporting base 101. As shown in FIG. 1, the substrate W is placed on the supporting base 101. After that, the controller controls the second actuator 106 to drive the supporting ring 103 to move upward (or the supporting base 101 to move downward) according to the feedback from the pressure sensor 107, so that the supporting base 101 and the supporting ring 103 jointly support the substrate W. As shown in FIG. 2, the supporting ring 103 supports the peripheral area of the substrate W, the supporting base 101 supports the central area of the substrate W, and the actual contact pressure between the substrate W and the supporting ring 103 is within the set contact pressure threshold.

At the moment when the supporting ring 103 contacts the peripheral area of the substrate W, the contraction of the buffer portion 1041 will generate a buffering force that can absorb part of the impact force formed between the supporting ring 103 and the substrate W during their contact. This avoids problems such as warping, fragmenting, and poor contact of the substrate W due to impact force, ensuring that the contact between the substrate W and the supporting ring 103 is smoother and more reliable, and ensuring that the substrate W is in close contact with the support seat 101 and the supporting ring 103. This not only helps eliminate the gap between the substrate W and the substrate supporting component 10, thereby preventing the reactive gas from entering the backside of the substrate W along the gap during the film deposition process, which would lead to undesired backside deposition, but also improves the heat conduction efficiency of the supporting base 101 and the supporting ring 103 to the substrate W, thus enhancing the uniformity of the surface temperature of the substrate W and improving the uniformity of the film deposition.

### Process Stage of Substrate W

The substrate W is supported by the supporting base 101 and the supporting ring 103. The central area and peripheral area of the substrate W are heated by the first heater 1011 and the second heater 1031 respectively. The gas distributor 20 supplies reactive gas to the surface of the substrate W to perform a film deposition process. After the film deposition is completed, the second actuator 106 again drives the supporting ring 103 to move upward (or the supporting base 101 to move downward), causing the substrate W to separate from the supporting base 101. The substrate W is individually supported by the supporting ring 103, after which the first actuator 105 drives the supporting ring 103 to carry the substrate W to rotate at a predetermined angle. This angle adjustment of the substrate W during the film deposition process achieves better film flatness. After that, the second actuator 106 drives the supporting ring 103 move to downward (or the supporting base 101 to move upward), so that the supporting ring 103 and the supporting base 101 jointly support the substrate W, and then the next step of the film deposition process is performed on the substrate W. According to the process settings, multiple rotations of the substrate W and film deposition are completed to form a predetermined film stack structure on the surface of the substrate W.

The controller can also control the second actuator 106 to drive the supporting ring 103 to move downward (or the supporting base 101 to move upward) based on the feedback from the pressure sensor 107, so that when the supporting base 101 and the supporting ring 103 jointly support the substrate W, the actual contact pressure between the substrate W and the supporting ring 103 is within the set contact pressure threshold.

During the process stage of the substrate W, the first gas path can remain open, and several first exhausts 1013 supply gas to the gap between the supporting base 101 and the supporting ring 103. On the one hand, this gas can form a gas curtain at the outer edge of the substrate W, preventing the reactive gas from entering the backside of substrate W, thus avoiding unnecessary backside deposition and reducing adverse effects such as particle contamination on the film deposition process. On the other hand, this gas (which can be selected as a heated gas according to process needs) not only can conduct heat conduction (or heat) to the area of the substrate above the gap between the supporting base 101 and the supporting ring 103, but also can improve the heat transfer efficiency of the supporting ring 103 to the peripheral area of substrate W, thus allowing substrate W to be heated more uniformly and achieving a well-performing film on the surface of the substrate W.

### Outgoing Stage of Substrate W

After multiple rotations of the substrate W and film deposition are completed according to the process settings, the lifting pin 1017 rises to lift the substrate W. At this time, the substrate W is separated from the supporting ring 103 and the supporting base 101 and only supported by the lifting pin 1017. The robotic arm is inserted between the substrate W and the supporting base 101, making contact with the substrate W. Subsequently, the lifting pin 1017 descends below the surface of the supporting base 101, the substrate W is separated from the lifting pin 1017, and the robotic arm transfers the substrate W out of the treatment chamber 100.

### Embodiment 2

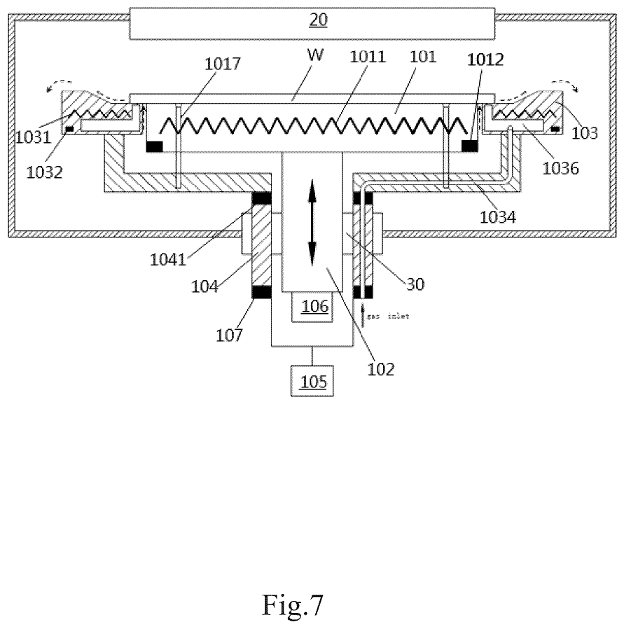

Referring to FIGS. 7 to 9, this embodiment provides a film deposition device. Compared to embodiment 1, in this embodiment, the first gas path set in the supporting base 101 and the central shaft 102 and the several first exhaust 1013 located on the outer circumferential surface of the supporting base 101 are canceled. A second gas path is set in the supporting ring 103 and the rotary shaft 104, and several second exhausts 1033 are set on the inner circumferential surface of the supporting ring 103. Other structures are the same as in the embodiment 1.

Referring to FIGS. 7 to 9, the second gas path includes a second gas source (not shown), a second main gas path 1034 and a second buffer chamber 1036 that are connected in sequence. The second gas source is used to provide gas. The second main gas path 1034 is provided in the rotary shaft 104. The second buffer chamber 1036, located inside the supporting ring 103, is an annular chamber coaxial with the supporting ring 103. Wherein, the second main gas path 1034 connects the second gas source and the second buffer chamber 1036, while the second buffer chamber 1036 connects several second exhausts 1033.

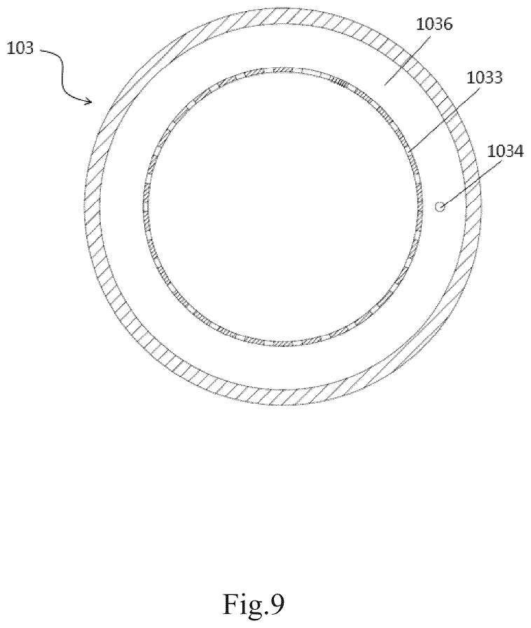

As shown in FIG. 9, several second exhaust 1033 are evenly distributed on the inner circumferential surface of the supporting ring 103 and are connected to the second buffer chamber 1036. Gas is supplied to the gap between the supporting base 101 and the supporting ring 103 through several second exhausts 1033, which can not only form a gas curtain on the outer edge of the substrate W to prevent the reactive gas in the treatment chamber 100 from escaping into the backside of the substrate W, forming an unnecessary backside deposition affects product yield, but it can also effectively improve the heating uniformity of the substrate W, thereby improving the uniformity of the film on the substrate W surface.

The above embodiment only illustrates the principles and effects of the present invention, but is not intended to limit the invention. Anyone familiar with this technology may modify or change the above embodiment without deviating from the spirit and scope of this invention. Therefore, all equivalent modifications or changes made by those with ordinary knowledge in the technical field without departing from the spirit and technical ideas disclosed in the present invention shall still be covered by the claims of the present invention.

What is claimed is:

1. A film deposition device, having a substrate supporting component, wherein the substrate supporting component comprises:
a supporting base and a central shaft, with the supporting base being fixed on the top of the central shaft for supporting the central area of the substrate;
a supporting ring and a rotary shaft, with the supporting ring being fixed on the top of the rotary shaft and arranged around the supporting base for supporting the peripheral area of the substrate;
a first actuator, connected to the rotary shaft and used to drive the supporting ring to rotate;
a second actuator, used to drive the supporting ring and the supporting base to move relative to each other in a vertical direction;
a buffer portion, for buffering when the substrate contacts the supporting ring.

2. The film deposition device according to claim 1, wherein the buffer portion is set on the rotary shaft.

3. The film deposition device according to claim 1, wherein the substrate supporting component further comprises:
a pressure sensor, used to detect an actual contact pressure between the substrate and the supporting ring;
a controller, used to control the relative movement distance of the supporting ring and the supporting base according to the actual contact pressure detected by the pressure sensor, so that the actual contact pressure between the substrate and the supporting ring is within a set contact pressure threshold.

4. The film deposition device according to claim 3, wherein the pressure sensor is set below the rotary shaft.

5. The film deposition device according to claim 1, wherein the second actuator is connected to the rotary shaft and drives the supporting ring to move in the vertical direction relative to the supporting base through the rotary shaft.

6. The film deposition device according to claim 1, wherein the second actuator is connected to the central shaft and drives the supporting base to move in the vertical direction relative to the supporting ring through the central shaft.

7. The film deposition device according to claim 1, wherein the substrate supporting component further comprises:
a first heater, used to heat the supporting base;
a first temperature sensor, used to detect the temperature of the supporting base.

8. The film deposition device according to claim 7, wherein the substrate supporting component further comprises:
a second heater, used to heat the supporting ring;
a second temperature sensor, used to detect the temperature of the supporting ring.

9. The film deposition device according to claim 8, wherein the first heater and the second heater are independently controlled.

10. The film deposition device according to claim 8, wherein the first heater is integrated with the supporting base, and the second heater is integrated with the supporting ring.

11. The film deposition device according to claim 1, wherein the outer circumferential surface of the supporting base is provided with several uniformly distributed first exhausts, and the several first exhausts are connected to a first gas path for supplying gas to the gap between the supporting base and the supporting ring.

12. The film deposition device according to claim 11, wherein the first gas path comprises:
a first gas source, used to provide gas;
a first main gas path, set in the central shaft;
multiple branch gas paths, radially distributed inside the supporting base;
a first buffer chamber, being set inside the supporting base and being an annular chamber coaxial with the supporting base;
wherein, the first main gas path is connected to the first gas source and multiple branch gas paths, and the first buffer chamber is connected to multiple branch gas paths and several first exhausts.

13. The film deposition device according to claim 1, wherein the inner circumferential surface of the supporting ring is provided with several uniformly distributed second exhausts, and the several second exhausts are connected to a second gas path for supplying gas to the gap between the supporting base and the supporting ring.

14. The film deposition device according to claim 13, wherein the second gas path comprises:
a second gas source, used to provide gas;
a second main gas path, set in the rotary shaft;
a second buffer chamber, being set inside the supporting ring and being an annular chamber coaxial with the supporting ring;
wherein, the second main gas path is connected to the second gas source and the second buffer chamber, and the second buffer chamber is connected to several second exhausts.

15. The film deposition device according to claim 1, wherein the supporting base is an electrostatic chuck, and the same electrode is provided in the supporting ring as in the supporting base for electrostatic adsorbing the peripheral area of the substrate.

16. The film deposition device according to claim 1, further comprising:
a treatment chamber, in which the substrate supporting component is located to support the substrate to be processed, wherein the rotary shaft and the central shaft of the substrate supporting component are sealed with the treatment chamber through magnetic fluid;
a gas distributor, located at the top of the treatment chamber and used to supply reactive gas into the treatment chamber to form a film on the surface of the substrate.
